(19) United States
(12) Patent Application Publication
(10) Pub. No.: US 2007/0190805 A1
(43) Pub. Date: Aug. 16, 2007

(54) METHOD FOR IMPROVING THE ALIGNMENT ACCURACY OF SEMICONDUCTOR PROCESS AND METHOD OF FORMING OPENING

(76) Inventor: Benjamin Szu-Min Lin, Hsinchu (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 11/307,507

(22) Filed: Feb. 10, 2006

(51) Int. Cl. H01L 21/31; H01L 21/302; H01L 21/76

(52) U.S. Cl. 438/778; 438/401; 438/975; 438/736

(57) ABSTRACT

A method of improving the alignment accuracy of the semiconductor devices is described. The method is used for photolithography process, and the photolithography process is aimed at the dielectric layer covered by a hard mask layer, wherein alignment marks are formed under the dielectric layer. The hard mask layer has an absorption index and a thickness, and the product of the absorption index multiplied by the thickness is between 100 and 750. Thereby, the better range of the thickness can be determined to improve the accuracy of alignment.

### BACKGROUND OF THE INVENTION

1. Field of the Invention

The present invention generally relates to an alignment method for semiconductors. More particularly, the present invention relates to a method for improving alignment accuracy of the semiconductor fabrication processes.

2. Description of Related Art

As well known in the art, photolithography is critical for the successful fabrication processes of semiconductor devices. Normally, depending on the complexity of the devices, it takes about 10 to 18 photolithographic and exposure processes to complete the fabrication processes of the devices. In order to correctly and accurately transfer the pattern to the chips during the semiconductor fabrication processes, the alignment between the chip and photomask has to be calculated carefully before each exposure, otherwise the chip will be wasted.

In the conventional exposure process, the alignment marks corresponding to the photomask are formed on the chips with desired semiconductor devices, in order to form a scattering site or a diffraction edge. The alignment marks are comprised of zero marks and floating non-zero marks, or metal alignment marker formed of metals and highly reflective to the light. As the alignment light beam irradiates onto the chip, the diffraction pattern resulted from the alignment mark will be reflected to the alignment sensor, or the First Order Diffraction Interferometer Alignment System, so as to achieve the alignment.

Through the photolithographic process, a hard mask layer is commonly formed as a mask for the following etching process to prevent damage toward the regions that is not planned to be etched during the etching process. However, as the hard mask layer is too thick, most of the alignment light beam will be absorbed by the hard mask layer and the alignment accuracy is reduced. Sometimes, if the alignment light bean is completely absorbed and unable to pass the hard mask layer, the alignment failure will happen. On the other hand, if the thickness of the hard mask layer is not enough, it possesses no protective effects and the unexpected regions may be damaged during the etching process, thus reducing the reliability for the devices.

### SUMMARY OF THE INVENTION

Accordingly, the present invention is directed to provide a method of improving the alignment accuracy for the semiconductor fabrication processes by controlling the thickness of the hard mask layer, so that the light beam can effectively pass through the hard mask layer to improve the alignment precision.

In accordance with one aspect of the present invention, an alignment method for the semiconductor fabrication is provided, by means of controlling the thickness of the hard mask layer. Therefore the regions that are not planned to be etched will not be damaged during the etching process and the reliability of the devices can be improved.

In accordance with another aspect of the present invention, a method for forming an opening is provided, which provides openings with excellent alignment accuracy.

In accordance with yet another aspect of the present invention, a method for improving the precision for the alignment is provided, applied for the photolithographic process aiming at the dielectric layer covered with the hard mask layer. The alignment marks are disposed under the dielectric layer and the hard mask layer has an absorption index and a thickness. The product of the absorption index and the thickness is around 100˜750. Furthermore, the etching ration of the dielectric layer to the hard mask is bigger than 5.

According to a preferred embodiment of the present invention, the material for the hard mask layer can be, for example, titanium nitride (TiN) or tantalum nitride (TaN).

According to a preferred embodiment of the present invention, titanium nitride (TiN) is used as the material of the hard mask layer, and the range for the thickness, for example, can be around 325 Å˜475 Å.

According to a preferred embodiment of the present invention, tantalum nitride (TaN) is used as the material of the hard mask layer, and the range for the thickness, for example, can be around 175 Å˜275 Å.

According to a preferred embodiment of the present invention, the material for the alignment marker can be, for example, copper (Cu).

In accordance with again another aspect of the present invention, an alignment method for the semiconductor fabrication processes is provided and the processes involved in forming a plurality of alignment markers and a plurality of conductive lines, forming a dielectric layer to cover the alignment markers and conductive lines, and forming a hard mask layer formed over the dielectric layer. The hard mask layer has an absorption constant and a thickness, which the product for the absorption constant and thickness is around 100˜750. Furthermore, the etching ration of the dielectric layer to the hard mask is bigger than 5. Then, a photoresist layer is formed over the hard mask layer. Thereafter, the aligned light beam is used for detection of the alignment marker, which enable the pattern of the photomask to be accurately transferred to the photoresist layer.

According to another preferred embodiment of the present invention directed to the method for the alignment process in fabricating semiconductor, the steps for forming the alignment markers and the conductive lines are comprised of forming a plurality of trenches inside the substrate and filling a metal layer inside the trenches.

According to another preferred embodiment of the present invention, the materials for the alignment markers and the conductive lines are comprised of, for example, copper (Cu).

According to another preferred embodiment of the present invention, the steps for forming the alignment markers and the conductive lines are comprised of forming a metal layer over the substrate, them defining the metal layer to form the alignment marker and conductive lines.

According to another preferred embodiment of the present invention, the materials for the alignment markers and the conductive lines are comprised of, for example, aluminum (Al).

According to another preferred embodiment of the present invention, the materials for the dielectric layer are comprised of, for example, silicon dioxide.

In accordance with another aspect of the present invention, a method for forming an opening applicable for the fabrication of interconnects is provided. The steps are comprised of forming a plurality of alignment markers and a plurality of conductive lines over the substrate, and forming a dielectric layer over the substrate and covering the alignment markers and conductive lines. Then a hard mask layer is formed over the dielectric layer, where the hard mask layer has an absorption constant and a thickness, and the product for the absorption constant and thickness is around 100˜750. Furthermore, the etching ration of the dielectric layer to the hard mask is bigger than 5. Then, a photoresist layer is formed over the hard mask layer. Through the alignment markers, the pattern is transferred to the photoresist layer. Thereafter, the patterned photoresist layer is treated as a mask to remove a portion of the hard mask layer. Then, the hard mask layer is used as the mask to remove a portion of the dielectric layer till exposing those conductive lines.

Though controlling the thickness of the hard mask layer, the present invention affords high alignment precision by allowing the light beam effectively passing through the hard mask layer and the light beam being reflected by the alignment marker to the detector. On the other hand, the alignment method of the present invention will not lose protective (anti-etching) effects even when the hard mask layer is not thick. Besides, the method of this invention can be integrated to the current semiconductor fabrication processes without additional equipments required. Moreover, by using the method for forming openings described in this invention, the pattern and position of the openings formed are with high precision, thus improving the reliability of the semiconductor devices.

It is to be understood that the foregoing general description and the following detailed description are exemplary and explanatory only and are not restrictive of the invention, as claimed.

### BRIEF DESCRIPTION OF THE DRAWINGS

FIG. 1 is the diagram to illustrate the attenuated intensity vs the thickness of the hard mask layer according to one preferred embodiment of the present invention.

FIGS. 2A to 2B are the cross sectional views of the fabrication processes for the opening according to one preferred embodiment of the present invention.

FIGS. 3A to 3C are the cross sectional views of the fabrication processes for the opening according to another preferred embodiment of the present invention.

### DESCRIPTION OF THE EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

In general, during the photolithographic process, a dielectric layer is formed over the alignment markers and a hard mask layer is further formed over the dielectric layer. The material for the alignment markers can be, for example, a metal, and the material for the hard mask layer can be, for example, Titanium nitride (TiN) or Tantalum nitride (TaN). Furthermore, the etching ration of the dielectric layer to hard mask is bigger than 5. Then, the alignment light beam onto the alignment markers generates a diffraction pattern through the alignment markers and the diffraction pattern being reflected to the alignment detector or the first order diffraction interferometer alignment system is used to achieve the alignment. It is noted that the thickness of the hard mask layer will affect the precision (or accuracy) of the alignment during the alignment process.

The equation for the thickness of the hard mask layer according to the present invention is as follows:
Exp (−2×thickness×absorption constant)>attenuated intensity.

The absorption index=4πk/λ

Where “Exp.” is representing the natural log; “thickness” is the thickness of the hard mask layer by using Å as the unit; “absorption constant” is the absorption coefficient of the hard mask layer with the “1/Å” as the unit, and the absorption constant will change according to the materials of the hard mask layer; k is the absorption index, λ is the wave length. The “attenuated intensity” is the attenuated intensity of the alignment light beam.

According to the preferred embodiments of the present invention, the attenuated intensity can be, for example, 5%, therefore, the product of absorption index and thickness preferably ranges between 100˜750 (as shown in the following equation).
100<thickness×absorption index<750

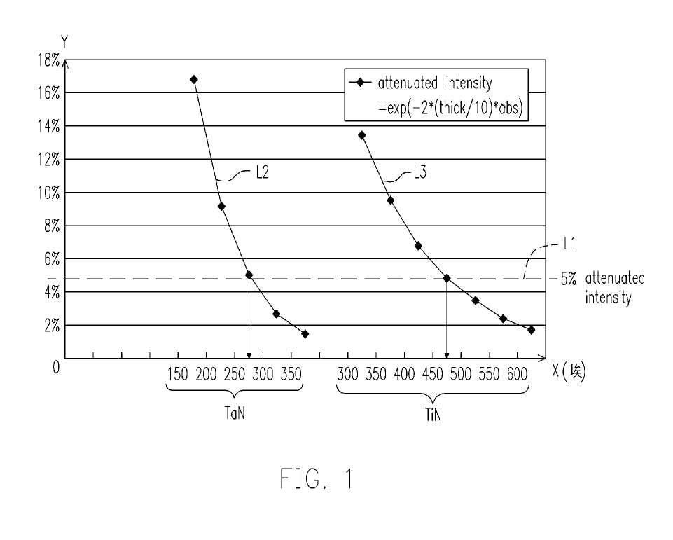

Regarding the equation 1 in FIG. 1, FIG. 1 illustrates the diagram to present the attenuated intensity vs the thickness of the hard mask layer according to one preferred embodiment of the present invention. Referring to FIG. 1, X axis represents the thickness of the hard mask layer and the Y axis represents the attenuated intensity. The equation of the FIG. 1: attenuated intensity=EXP (−2×(thickness/10)×absorption constant) can be applied to curve L2 and curve L3. The dotted line L1 in the FIG. 1 illustrates the curve with the attenuated intensity of 0.05; the curve L2 illustrates the relationship between Tantalum nitride (TaN) and the attenuated intensity; the curve L3 illustrates the relationship between Titanium nitride (TiN) and the attenuated intensity. According to FIG. 1, if the set value of the attenuated intensity for the present invention is bigger than 5%, the preferred thickness range for Tantalum nitride (TaN) can be around 175 Å˜275 Å and the preferred thickness range for Titanium nitride (TiN) can be around 325 Å˜475 Å.

The range of the product of the thickness and the absorption index according to the above embodiments of the present invention is not to limited to these two materials, Tantalum nitride (TaN) and Titanium nitride (TiN). As long as the material is appropriate for the hard mask layer, it is applicable for the range of the product of the thickness and the absorption index.

Therefore, by applying the absorption index of the chosen material into the equation for the range of the product of thickness and absorption index, the preferred thickness range for the hard mask layer can be obtained, in order to improve the alignment precision without losing the anti-etching effect due to the insufficient thickness.

The following paragraphs relate to another embodiment of the present invention, to illustrate the application for the method for improving the alignment precision.

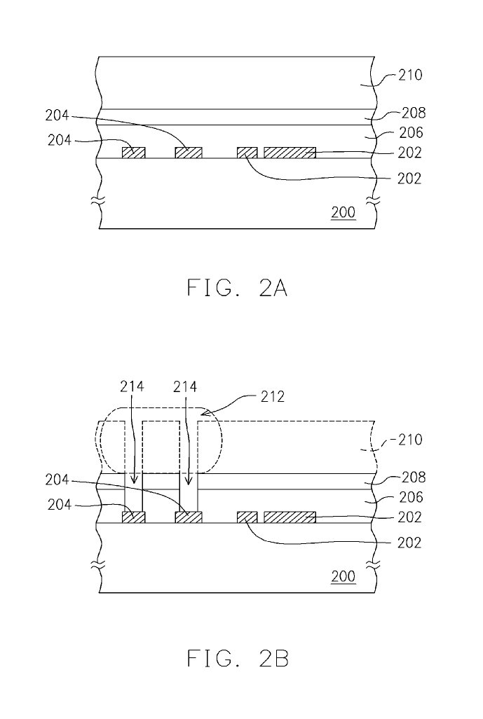

FIGS. 2A-2B illustrate the cross sectional views of the fabricating process for the opening according to the preferred embodiments of the present invention. As shown in FIG. 2A, a plurality of alignment markers 202 and a plurality of conductive lines 204 are formed on the substrate 200, where the material for the substrate can be, for example, silicon and the materials for alignment markers 202 and conductive lines 204 can be a metal, for example, aluminum. The method for the formation of alignment markers 202 and conductive lines 204 comprises, for example, depositing an aluminum metal layer (not show) on the semiconductor substrate 200 and patterning the aluminum metal layer.

Next, continuing FIG. 2A, a dielectric layer 206 is formed over the substrate 200 to cover the alignment markers 202 and the conductive lines 204. The material for the dielectric layer is, for example, silicon dioxide, and the formation method is, for example, chemical vapor deposition.

Then, turning to FIG. 2A, a hard mask layer 208 is formed with an absorption constant and a thickness. The product of the absorption constant and the thickness for the hard mask layer 208 is ranged around 100˜750, and the etching ratio of the dielectric layer 206 to the hard mask 208 is bigger than 5. The material for the hard mask layer can be, for example, Tantalum nitride (TaN) and the preferred thickness is ranged around 175 Å˜275 Å, formed by, for example, chemical vapor deposition. In the other preferred embodiment, the material for the hard mask layer can be, for example, Titanium nitride (TiN) and the preferred thickness is ranged around 325 Å˜475 Å.

Referring next to FIG. 2A, a photoresist layer 210 is formed over the hard mask layer 208, by, for example, spin coating. Thereafter, a mask is provided (not shown in the figures) and an alignment light beam is used for detecting the alignment markers 202, in order to transfer the pattern to the photoresist layer 210 accurately.

Referring now to FIG. 2B, a plurality of openings 214 is formed inside the dielectric layer 206 and each opening corresponds to one of the conductive lines 204. The formation method for the openings 214 includes, for example, exposing and developing the photoresist layer 210 (FIG. 2A), in order to transfer the pattern 212 to the photoresist layer 210, using the patterned photoresist layer 210 (with the pattern 212) as a mask to remove a portion of hard mask layer 208, for example, by etching, and then using the hard mask layer 208 as a mask to remove a portion of dielectric layer 206 till the conductive line 204 is exposed to form the openings 214. Then, the photoresist layer 210 is removed. Regarding the rest of the processes are known to skills in the arts, therefore, no more descriptions will be detailed.

According to yet another preferred embodiment of the present invention, the above mentioned formation steps for the opening 214 can be performed after removing a portion of hard mask layer 208 by using the patterned photoresist layer 210 as a mask. The photoresist layer 210 is removed first, and then a portion of dielectric layer 206 is removed to expose conductive line 204 by using the hard mask layer 208 as a mask.

The above mentioned embodiment applies the alignment markers 202 and the alignment light beam for the alignment, therefore, the openings 214 can be positioned accurately and the reliability of the semiconductor devices can be improved. on the other hand, the fabrication process of the present invention can be integrated with the current processes, so that no additional cost will be added.

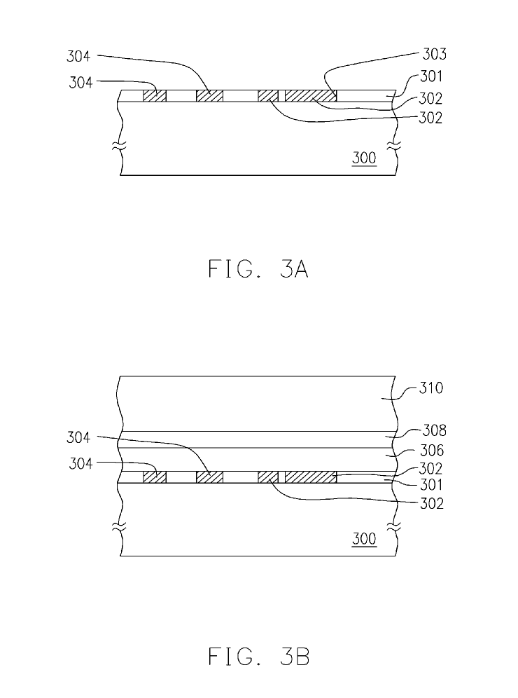

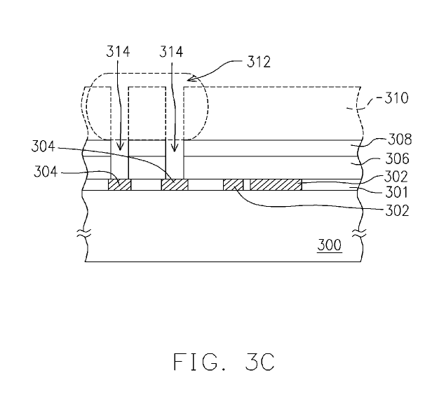

FIG. 3A to FIG. 3C are the cross sectional views of the fabrication process for the opening according to yet again another preferred embodiment of the present invention. Referring now to FIG. 3A, a plurality of alignment markers 302 and a plurality of conductive lines 304 are formed on the semiconductor substrate 300. The semiconductor substrate 300 can be, for example, a silicon substrate and the materials for the alignment markers 302 and conductive lines 304 can be a metal, for example, copper (Cu). The method for forming the alignment markers 302 and conductive lines 304 includes, for example, forming a dielectric layer 301 over the substrate 300, with a plurality of trenches 303 formed in the dielectric layer 301. Then, a metal layer (not shown) is filled into the trenches 303 on the dielectric layer 301, and the material is, for example, copper (Cu), by, for example, chemical vapor deposition. Then, the extra metal over the dielectric layer 301 is removed, by, for example, chemical mechanical polishing and using the dielectric layer 301 as a stop layer to form the alignment markers 302 and conductive lines 304.

Thereafter, with reference to FIG. 3B, a dielectric layer 306 is formed over the semiconductor substrate 300, and covers the alignment markers 302 and conductive lines 304. The material, for example, is silicon dioxide formed by chemical vapor deposition.

Continuing to FIG. 3B, a hard mask layer 308 is formed over the dielectric layer 306, where the hard mask layer 308 has an absorption constant and a thickness, and the product for the absorption constant and thickness is around 100˜750, and the etching ratio of the dielectric layer 306 to the hard mask 308 is bigger than 5. The material for the hard mask layer is, for example, Tantalum nitride (TaN) and the preferred thickness is ranged around 175 Å˜275 Å, by, for example, chemical vapor deposition. In the other preferred embodiment, the material for the hard mask layer can be, for example, Titanium nitride (TiN) and the preferred thickness is ranged around 325 Å˜475 Å.

Then, continuing to FIG. 3B, a photoresist layer 310 is formed over the hard mask layer 308, by spin coating. Thereafter, a mask is provided (not shown in the figures) and an alignment light beam is used to detect the alignment markers 302, in order to transfer the pattern to the photoresist layer 310 accurately.

Referring to now to FIG. 3B, a plurality of openings 314 is formed inside the dielectric layer 306 and each opening 314 corresponds to one of the conductive lines 304. The formation method for the opening 314 includes, for example, exposing and developing the photoresist layer 310 (FIG. 3B), in order to transfer the pattern 312 to the photoresist layer 310, using the patterned photoresist layer 310 with the pattern 312 as a mask to remove a portion of hard mask layer 308, by, for example, etching, and using the hard mask layer 308 as a mask to remove a portion of dielectric layer 306 till the conductive line 304 is exposed to form the opening 314. Where the removal for a portion of dielectric layer 306 is performed by, for example, an etching process. Then the photoresist layer 310 is removed. Regarding the rest of the processes are known to skills in the arts, therefore, no more descriptions will be detailed.

According to yet again another preferred embodiment of the present invention, the above mentioned formation steps for the opening 314 can be done after removing a portion of hard mask layer 308 by using the photoresist layer 310 with pattern 312 as a mask. The photoresist layer 310 is removed, and then a portion of dielectric layer 306 is removed to expose conductive line 304 by using the hard mask layer 308 as a mask.

The above mentioned embodiment applies the alignment markers 302 and the alignment light beam for the alignment, therefore, the opening 314 can be positioned accurately and the reliability of the semiconductors devices can be improved. on the other hand, the fabrication processes of the present invention can be integrated with the currently applied processes, so that no additional equipment is required and no further cost will be added.

Although the above mentioned embodiments apply the alignment method to the fabrication of openings for the metal interconnects, it is not intended to limit the present invention to the precise forms disclosed. Thereby enabling others skilled in the art to utilize the invention in its various embodiments and modifications according to the particular purpose contemplated. The scope of the invention is intended to be defined by the claims appended hereto and their equivalents.

In conclusion of the above description, the present invention provides at least the following advantages:

1. According to the present invention, various materials can be applied to be the hard mask layer with suitable thickness range to improve the alignment precision and remain the anti-etching function.

2. According to the present invention, the alignment method provided herein can be integrated with the current fabrication processes. Therefore, no additional equipment should be purchased and the alignment precision can be improved.

3. According to the formation method of the openings of present invention, the pattern and positions of the openings are with high precision, which improves the reliability of the semiconductor devices.

The embodiments chosen and described are in order to explain the principles and the application of the invention, thereby enabling others skilled in the art to utilize the invention in its various embodiments and modifications according to the particular purpose contemplated. The scope of the invention is intended to be defined by the claims appended hereto and their equivalents.

What is claimed is:

1. A method for improving an alignment precision for semiconductor devices, applicable for a photolithographic process, the method comprising:
applying the photolithographic process to a dielectric layer that is covered by a hard mask layer, wherein an alignment marker is formed under the dielectric layer, and wherein the hard mask layer has an absorption index and a thickness and a product of the absorption constant and the thickness is about 100˜750; and
the etching ratio of the dielectric layer to the hard mask is bigger than 5.

2. The method as recited in claim 1, wherein a material for the hard mask layer is comprised of a Titanium nitride (TiN) or Tantalum nitride (TaN).

3. The method as recited in claim 2, wherein a thickness of the hard mask layer, if Titanium nitride (TiN) is used as the material for the hard mask, ranges between about 100 Å˜475 Å.

4. The method as recited in claim 2, wherein a thickness of the hard mask layer, if Tantalum nitride (TaN) is used as the material for the hard mask layer, ranges between about 100 Å˜275 Å.

5. The method as recited in claim 1, wherein a material for the alignment marker is comprised of a metal.

6. An alignment method for semiconductor devices, comprising:
forming a plurality of alignment markers and a plurality of conductive lines on a substrate;
forming a dielectric layer over the substrate and covers the alignment markers and conductive lines;
forming a hard mask layer over the dielectric layer, wherein the hard mask layer has an absorption index and a thickness, and a product of the absorption index and the thickness is ranged between about 100˜750; and
the etching ratio of the dielectric layer to the hard mask is bigger than 5;
forming a photoresist layer over the hard mask layer; and
applying a light beam onto the alignment markers to transfer a pattern of a photomask to the photoresist layer.

7. The method as recited in claim 6, wherein the hard mask layer is further comprised of a Titanium nitride (TiN) layer.

8. The method as recited in claim 7, wherein a thickness for the Titanium nitride (TiN) layer ranges between about 325 Å˜475 Å.

9. The method as recited in claim 6, wherein the hard mask layer is further comprised of a Tantalum nitride (TaN) layer.

10. The method as recited in claim 9, wherein a thickness for the Tantalum nitride (TaN) layer ranges between about 175 Å˜275 Å.

11. The method as recited in claim 6, wherein the steps of forming the alignment markers and the conductive lines comprises:
forming a plurality of trenches in the substrate; and
filling the trenches with a metal layer.

12. The method as recited in claim 11, wherein materials for the alignment markers and the conductive lines are comprised of copper (Cu).

13. The method as recited in claim 6, wherein the steps for forming the alignment markers and conductive lines are comprised of:
forming a metal layer on the substrate; and
defining the metal layer to form the alignment markers and the conductive lines.

14. The method as recited in claim 13, wherein materials for the alignment markers and the conductive lines are comprised of aluminum (Al).

15. The method as recited in claim 6, wherein a material for the dielectric layer is comprised of silicon dioxide.

16. A method of forming an opening, applicable for interconnects of semiconductor processes, comprising:
forming a plurality of alignment markers and a plurality of conductive lines on a substrate;
forming a dielectric layer over the substrate, wherein the dielectric layer covers the alignment markers and conductive lines;
forming a hard mask layer over the dielectric layer, wherein the hard mask layer has an absorption constant and a thickness, and a product of the absorption index and the thickness ranges between about 100˜750, and the etching ratio of the dielectric layer to the hard mask is bigger than 5;
forming a photoresist layer over the hard mask layer;
transferring a pattern to the photoresist layer according to the alignment markers;
removing a portion of the hard mask layer by using the patterned photoresist layer as a first mask;
removing a portion of the dielectric layer till the conductive lines are exposed by using the hard mask layer as a second mask.

17. The method as recited in claim 16, wherein the hard mask layer is further comprises of a Titanium nitride (TiN) layer.

18. The method as recited in claim 17, wherein a thickness for the Titanium nitride (TiN) layer ranges between about 325 Å˜475 Å.

19. The method as recited in claim 16, wherein the hard mask layer is further comprises of a Tantalum nitride (TaN) layer.

20. The method as recited in claim 19, wherein a thickness for the Tantalum nitride (TaN) layer ranges between about 175 Å˜275 Å.

21. The method as recited in claim 16, wherein the steps of forming the alignment markers and the conductive lines comprises:
forming a plurality of trenches in the substrate; and
filling the trenches with a metal layer.

22. The method as recited in claim 21, wherein materials for the alignment markers and the conductive lines are comprised of copper (Cu).

23. The method as recited in claim 16, wherein the steps for forming the alignment markers and the conductive lines are comprised of:
forming a metal layer on the substrate; and
defining the metal layer to form the alignment markers and the conductive lines.

24. The method as recited in claim 23, wherein materials for the alignment markers and the conductive lines are comprised of aluminum (Al).

25. The method as recited in claim 16, wherein a material for the dielectric layer is comprised of silicon dioxide.
